(19) United States
(12) Patent Application Publication
(10) Pub. No.: US 2012/0321101 A1
(43) Pub. Date: Dec. 20, 2012

(54) WIRELESS MIC SYSTEM FOR AUTOMATICALLY PARING

(75) Inventor: Kang-Seok LEE, Seoul (KR)

(73) Assignee: EARZONE CO., LTD., Seoul (KR)

(21) Appl. No.: 13/473,511

(22) Filed: May 16, 2012

(30) Foreign Application Priority Data
Jun. 20, 2011 (KR) 10-2011-0059615

(51) Int. Cl. H03F 99/00; H04B 15/00

(52) U.S. Cl. 381/94.1; 381/120

(57) ABSTRACT

Disclosed is a wireless MIC system for automatically paring, which comprises a wireless MIC which includes a paring button at its one side and facilitates a connection mode as it is automatically paired with an amplifier by transmitting a paring request signal when the paring button is on, and initializes a connection related information stored in a storing part when the connection mode is cancelled and converts an acoustic signal into a digital audio signal and transmits to the paired amplifier; and an amplifier which facilitates a connection mode as the wireless MIC and the amplifier are paired by setting a transmission and receiving channel of the amplifier and the wireless MIC, and amplifies a digital audio signal from the wireless MIC and outputs in an acoustic form.

### TECHNICAL FIELD

The present invention relates to a wireless MIC (Microphone) system for automatically paring, and in particular to a wireless MIC system for automatically paring which provides a user with convenience when in use by automatically paring a wireless MIC and an amplifier when a user pushes an on button in such a way to provide a wireless MIC facilitating an automatic paring with an amplifier by transmitting a paring request signal when a paring button is on and to provide an amplifier paring a wireless MIC and an amplifier by setting a transmission and receiving channel between an amplifier and a wireless MIC when a paring request signal is received from a wireless MIC.

### BACKGROUND ART

The present invention is directed to a wireless MIC system for automatically paring.

The wireless MIC system is directed to a system receiving an audio signal from a MIC via a speaker device and converting into an acoustic signal and is widely used since it has an effect of resolving inconvenience in terms of a place occurring when using a conventional wireless MIC.

When a wireless MIC system is installed in huge size hall, a plurality of spaced-apart speaker devices receive an audio signal from a MIC.

When a wireless MIC system is used in an academy or a school, an audio signal from a MIC installed in the interior of a lecture room is received by a wireless speaker installed in the same lecture room, thus outputting acoustic sound.

In the above cases, an audio signal of a MIC in one lecture room might be received by a wireless speaker installed in another lecture room and might be outputted, so it is needed to make a wireless MIC and a wireless speaker, which are provided in the same space, paired.

The paring is directed to matching the devices for two separate wireless devices to communicate in safe and to avoiding any possibility that a data transmitted from a certain device is detected by or interfered with a device of another unknown person.

The conventional paring method is characterized in that wireless devices to be paired are placed near from each other and are matched as a paring button is pushed for a few seconds.

The conventional method, however, has inconveniences as a user is needed to manually pair wireless devices. For example, in order for a lecturer to provide lecture using a MIC in a lecture room of an academy with a lot of lecture rooms, it is needed to make paring with a wireless MIC installed in each lecture room for every lecture.

In the conventional art, a noise might occur while a MIC installed at a lecture room transfers signals via a wireless communication. In particular, when a distance between a MIC and a wireless speaker comes close, a howling phenomenon occurs. When the howling phenomenon occurs, a low frequency oscillation sound similar with noise is continuously generated, which interferes a communication between people.

### DISCLOSURE OF INVENTION

The present invention is made to resolve the above problems, and it is an object of the present invention to provide a wireless MIC system for automatically paring which makes it possible to provide a user with convenience when in use by resolving sanitation and storage problems since a MIC can be exclusively used by each user by automatically paring a wireless MIC and an amplifier when a user pushes a button in such a way to provide a wireless amplifier facilitating a connection mode as it is automatically pared with an amplifier by transmitting a pairing request signal when a paring button is on, and an amplifier facilitating a connection mode as a wireless MIC and an amplifier are paired by setting a transmission and receiving channel between an amplifier and a wireless MIC as a paring request signal is received from a wireless MIC.

It is another object of the present invention to provide a wireless MIC system for automatically paring which allows a plurality of users using a wireless MIC in a certain space such as lecture rooms to precisely communicate without howling in such a way to effectively reduce a howling phenomenon occurring in a wireless MIC system.

It is further another object of the present invention to provide a wireless MIC system for automatically paring which allows acoustic sounds inputted via multiple wireless MICs to be outputted via one amplifier by providing a plurality of wireless receiving chips so as to receive paring request signals and digital audio signals from a plurality of wireless MICs.

To achieve the above objects, there is provided a wireless MIC (microphone) system for automatically paring, comprising a wireless MIC which includes a paring button at its one side and facilitates a connection mode as it is automatically paired with an amplifier by transmitting a paring request signal when the paring button is on, and initializes a connection related information stored in a storing part when the connection mode is cancelled and converts an acoustic signal into a digital audio signal and transmits to the paired amplifier; and an amplifier which facilitates a connection mode as the wireless MIC and the amplifier are paired by setting a transmission and receiving channel of the amplifier and the wireless MIC, and amplifies a digital audio signal from the wireless MIC and outputs in an acoustic form.

In addition, the amplifier comprises a plurality of wireless receiving chips which receive a paring request signal and a digital audio signal from the plurality of the wireless MICs; and a channel process part which allows each wireless MIC to transmits a digital audio signal by using a transmission and receiving channel based on an advanced adaptive frequency hopping method when digital audio signals are transmitted from the plurality of the wireless MICs.

In addition, the amplifier comprises a howling inhibition circuit which judges whether a howling has happened by detecting a change of a digital audio signal from a wireless MIC, and eliminates a howling by adjusting a gain value of a digital audio signal when it is judged that a howling has happened.

In addition, the amplifier comprises a plurality of input terminals which are formed at one side of the amplifier and receive a digital audio signal or a digital image signal from an external input device.

In addition, the amplifier comprises a tone adjustment input part which receives a command on a tone adjustment; a volume adjustment part which receives a command on a volume adjustment; a tone adjustment circuit which modulates a digital audio signal from the wireless MIC into a corresponding frequency for thereby adjusting to a certain tone value when a request for adjusting a tone is inputted from the tone adjustment input part; and a volume adjustment circuit which adjusts a digital audio signal from the wireless MIC to a certain volume valve when a request for adjusting a volume is received from the volume adjustment input part.

In addition, the wireless MIC comprises a paring button which receives a command on a paring with an amplifier; a central processing unit in which a paring request signal is transmitted to an amplifier when an on signal is received from the paring button, and a pin code of a wireless MIC is transmitted for a paring between the devices when a paring approval signal and a pin code of an amplifier are received from the amplifier by transmitting a paring request signal to the amplifier, and an acoustic signal is converted into a digital audio signal in the connection mode as the devices are paired and, and is transmitted to a paired amplifier; and an initialization circuit which initializes by deleting a pin code information exchanged between the devices when a connection mode with the amplifier paired with the wireless MIC is cancelled.

In addition, the wireless MIC comprises a USB input terminal which is installed at one side of the wireless MIC and receives a DC voltage of a computer; and a charge process part which charges with a DC voltage inputted via the USB input terminal.

In addition, the wireless MIC comprises a LED installed at one side of the wireless MIC; a LCD installed at one side of the wireless MIC; a charge state judgment part which judges a charge state of a charge battery of the wireless MIC; a connection state judgment part which judges a connection state between the wireless MIC and the amplifier; and an information provision part which allows a result of the judgment of the charge state judgment part and the connection state judgment part to be outputted via the LED or the LCD.

In addition, the wireless MIC comprises an alarm part which process to output a charge suggestion message via the LED and the LCD when a charge level is below a previously set level as a result of the judgment of the charge state judgment part and processes to transmit a short message (SMS) informing a charge suggestion to a user of the wireless MIC.

### ADVANTAGEOUS EFFECTS

According to the present invention, it is possible to provide a user with convenience when in use by resolving sanitation and storage problems since a MIC can be exclusively used by each user by automatically paring a wireless MIC and an amplifier when a user pushes a button in such a way to provide a wireless amplifier facilitating a connection mode as it is automatically pared with an amplifier by transmitting a pairing request signal when a paring button is on, and an amplifier facilitating a connection mode as a wireless MIC and an amplifier are paired by setting a transmission and receiving channel between an amplifier and a wireless MIC as a paring request signal is received from a wireless MIC.

The present invention makes it possible to allows a plurality of users using a wireless MIC in a certain space such as lecture rooms to precisely communicate without howling in such a way to effectively reduce a howling phenomenon occurring in a wireless MIC system.

The present invention makes it possible as well to allow acoustic sounds inputted via multiple wireless MICs to be outputted via one amplifier by providing a plurality of wireless receiving chips so as to receive paring request signals and digital audio signals from a plurality of wireless MICs.

### BRIEF DESCRIPTION OF DRAWINGS

FIG. 1 is a view illustrating an entire construction of a wireless MIC system for automatically paring according to a preferred embodiment of the present invention.

FIG. 2 is a block diagram of an inner construction of a wireless MIC of FIG. 1.

FIG. 3 is a bock diagram of an inner construction of an amplifier of FIG. 1.

### BEST MODES FOR CARRYING OUT THE INVENTION

The preferred embodiments of the wireless MIC system for automatically paring according to the present invention will be described with reference to the accompanying drawings.

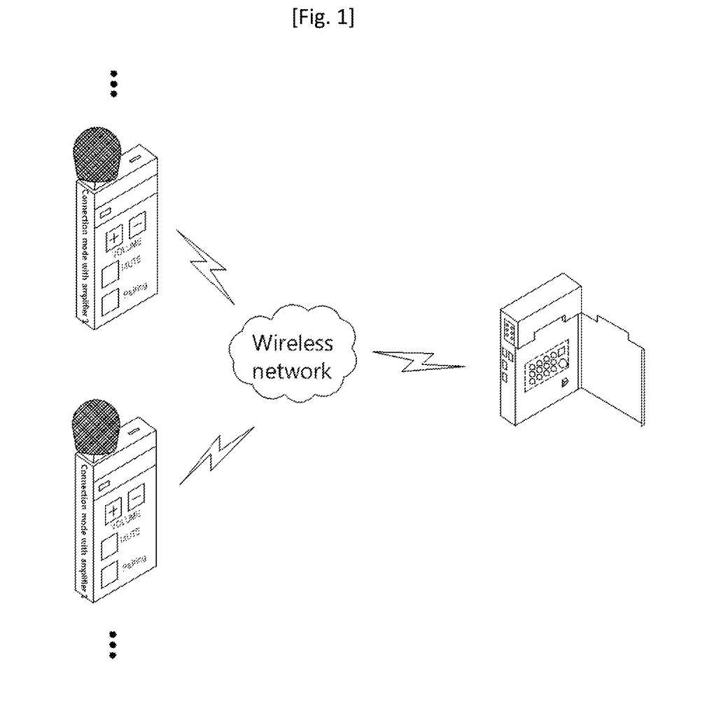

FIG. 1 is a view illustrating an entire construction of a wireless MIC system for automatically paring according to a preferred embodiment of the present invention.

The present invention comprises a plurality of wireless MICs carried by lecturers, and an amplifier 200 installed at every lecture room.

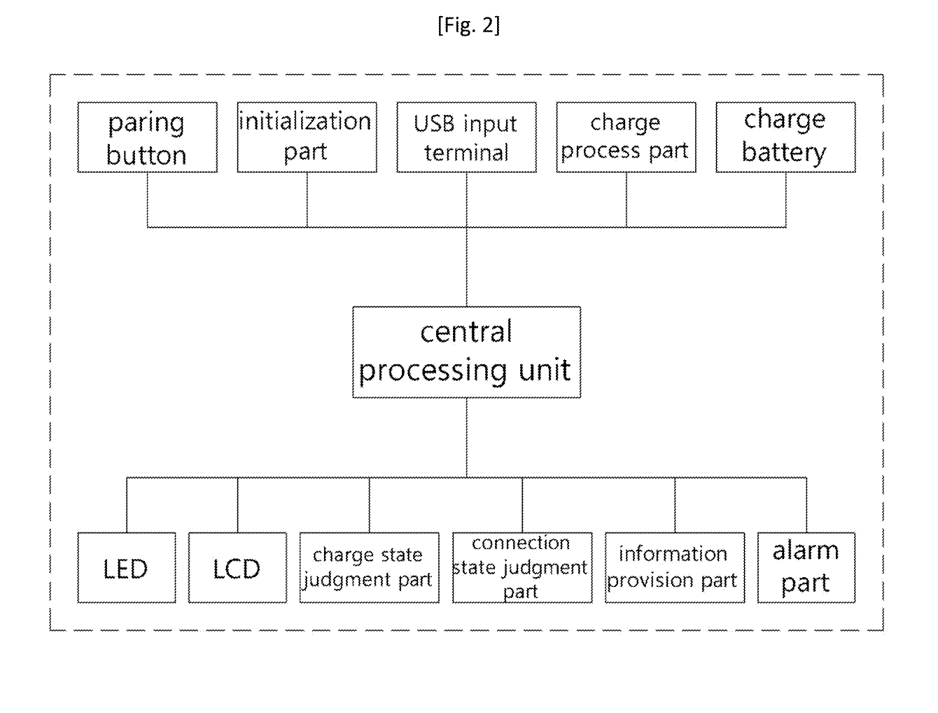

The wireless MIC 100 is characterized in that when a paring button 101 is on, a paring request signal is transmitted to an amplifier, and a wireless MIC and an amplifier are automatically paired, thus obtaining a connection mode, and when a connection mode is stopped, a connection related information stored in a storing part is initialized, and an acoustic signal received via an input part is converted into a digital audio signal and is transmitted to a paired amplifier. The wireless MIC 100 is made very light. The wireless MIC 100 is made in a form of a high performance pin type microphone, the construction of which allows a user to use both hands freely when in use. The wireless MIC 100 will be described in details with reference to FIG. 2.

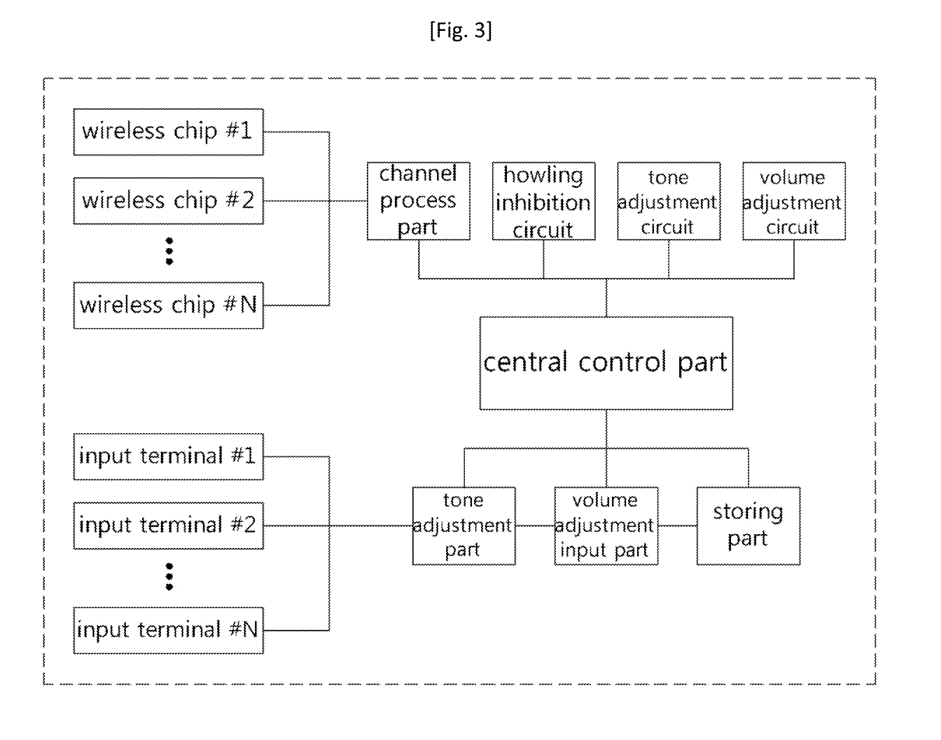

When a paring request signal from the wireless MIC 100 is received, the amplifier 200 sets a transmission and receiving channel between the amplifier 200 and the wireless MIC 100, thus forming a connection mode as the wireless MIC 100 and the amplifier 200 are paired, and the digital audio signal from the wireless MIC 100 is amplified, thus outputting acoustic sound. At this time, the amplifier 200 is preferably formed of a high performance digital amplifier (for example, RMS 100W), thus generating enough volume of sound. The amplifier 00 will be described in more detail with reference to FIG. 3.

According to the present invention, it is advantageous that a user can carry a wireless MIC without crosstalk in each lecture room, and since the lecturer can move carrying the wireless MIC, each user has an exclusive MIC operation. Since the MIC can be exclusively used for each user, the user can move anywhere carrying the MIC, and the storage is easy, and it is possible to prevent sanitation and crosstalk problems which occur when using a conventional MIC.

FIG. 2 is a block diagram of an inner construction of a wireless MIC of FIG. 1.

The wireless MIC 100 comprises a paring button 101, a volume adjusting button 102, a MUTE button 103, a central processing unit 110, an initialization part 120, a USB input terminal 130, a charging process part 140, a charging battery 150, a charge state judgment part 160, a connection state judgment part 170, an information provision part 180, an alarm part 185, a LED 190 and a LCD 195.

The paring button 101 is provided to receive a request command on a paring between the wireless MIC 100 and the amplifier 200.

The volume adjusting button 102 receives a command on the volume adjustment of the wireless MIC 100 and receives a command on adjusting the main volume of the amplifier 200.

The MUTE button 103 receives a command on a MIC in-use sound cancellation MUTE and can temporarily stop a sound output of the in-use wireless MIC 100 via the MUTE button 103.

The central processing unit 110 transmits a paring request signal to the amplifier 200 when receiving an on signal from the paring button 101, and transmits a pin code of the wireless MIC 100 for paring between the corresponding devices when a paring approval signal is received from the amplifier and a pin code of the amplifier is received. When in a connection mode as the corresponding devices are paired, an acoustic signal is converted into a digital audio signal and is transmitted to the paired amplifier.

When the central processing unit 110 adjusts the volume of a wireless MIC based on a button operation when a command in terms of the volume adjustment of the wireless MIC 100 is received via the volume adjustment button 102, and processes for the main volume adjustment signal of the amplifier to be transmitted to the paired amplifier 200 when a command of adjusting the main volume of the amplifier 200 is received via the volume adjustment button 102.

The initialization part 120 cancels and initializes the pin code information which was exchanged between the devices, when a connection mode with the paired amplifier 200 is cancelled when the wireless MIC 100 is out of the set range or by receiving an off signal via the paring button 101. When the connection mode is cancelled, the amplifier 200 deletes and initializes the pin code information exchanged between the devices.

As the connection mode is cancelled, when the information is initialized, the recorded paring connection information is deleted, so the crosstalk can be prevented when paired with another amplifier installed in another lecture room. If the initialization is not automatically performed, the amplifier (previously paired amplifier) installed in another lecture room might output an audio signal transmitted from the wireless MIC. The present invention is basically directed to resolving the above problems by providing the initialization part. So, the present invention is possible to pair the wireless MIC and the amplifier in an easier way without adapting an additional procedure or causing crosstalk.

The USB input terminal 130 is installed at one side of the wireless MIC 100 and serves to receive the DC voltage of the computer. The present invention is easy to charge in an easy way called a USB charge method.

The charge process part 140 is provided to charge the charge battery 150 using a DC voltage from the USB input terminal 130.

The charge state judgment part 160 is provided to check out the charge state of the charge battery 150 of the wireless MIC 100.

The connection state judgment part 170 is provided to judge the connection state between the wireless MIC 100 and the amplifier 200.

The information provision part 180 allows the result of the judgments of the charge state judgment part 160 and the connection state judgment part 170 to output via the LED 190 or the LCD 195 which is installed at one side of the wireless MIC 100.

The alarm part 185 is provided to output a charge suggestion message via the LED 190 or the LCD 195 when a charge level is below a set reference level as a result of the judgment of the charge state judgment part 160, and allows a SMS informing a charge suggestion to be transmitted to the user's terminal of the wireless MIC 100. With the above construction, the use is easy to check out the charge state of the MIC, thus preventing the discharge of the device in the course of the lecture in advance.

The LED 190 is installed at one side of the wireless MIC 100 and is provided to display the charge state of the wireless MIC 100 and the connection state with the amplifier 200.

The LED 195 is installed at one side of the wireless MIC 100 and displays a charge state of the wireless MIC 100 and a connection stat with the amplifier 200.

The storing part (not shown) is provided to store a pin code of the wireless MIC 100 and a user information of the wireless MIC and is provided to temporarily store the information of the paired amplifier in the connection mode.

FIG. 3 is a block diagram of the inner construction of the amplifier of FIG. 1.

As shown in FIG. 3, the amplifier 200 comprises a plurality of wireless chips 201, a plurality of input terminals 203, a channel process part 210, a howling inhibition circuit 220, a tone adjustment circuit 230, a volume adjustment circuit 240, a central control part 250, a tone adjustment input part 260, a volume adjustment input part 270 an a storing part 280.

The plurality of the wireless chips 201 are provided to receive a paring request signal and a digital audio signal from the plurality of the wireless MICs 100.

The plurality of the input terminals 203 are provided to receive a digital audio signal or a digital image signal from an external input device disposed at one side of the amplifier. In more details, the present invention is directed to maximizing the compatibility of the devices with the aid of a plurality of input terminals 203. For example, the present invention makes it possible to receive an input signal from a PC or a DVD player via a plurality of input terminals 203 and output the input signals for the purposes of a signal mixing, an external acoustic instrument connection, an audio device expansion, a wired MIC terminal support and a RGB signal distribution.

The channel processing part 210 is provided to transmit a digital audio signal using a transmission and receiving channel without any interference of each MIC based on an advanced adaptive frequency hopping when receiving a digital audio signal from the plurality of the wireless MICs 100. In other words, the present invention is directed to preventing crosstalk by adapting an automatic channel conversion method. As mentioned in the above, the present invention is advantages to effectively output the acoustic sounds from the plurality of the wireless MICs via one amplifier without interference occurring.

The channel process unit 210 is provided to implement a data exchange by setting a transmission and receiving channel for the purpose of exchanging data when a digital audio signal is received from one wireless MIC 100.

The howling inhibition circuit 220 is provided to judge whether or not a howling occurs by detecting any change in a digital audio signal from the wireless MIC 100, and is provided to eliminate the howling by adjusting a gain value of the digital audio signal in case that the howling is detected.

At this time, the howling inhibition circuit 220 is designed and programmed to judge the howling has occurred when the amplitude of the digital audio signal largely rises as compared to a reference level in a specific frequency region or continuously rises for a certain time period and then reaches a peak value.

The tone adjustment circuit 230 is provided to modulate a digital audio signal from the wireless MIC 100 to a certain tone value when a request for adjusting the tone via the tone adjustment input part 260 is received.

The volume adjustment circuit 240 is provided to adjust a digital audio signal from the wireless MIC 100 to a certain volume level when a request for adjusting the volume via the volume adjustment input part 270 is received.

The central control part 250 is provided to process the main volume of the amplifier 200 depending on the adjustment signal when a main volume adjustment signal of the amplifier 200 is received from the wireless MIC 100.

The central control part 250 is provided to delete the pin code exchanged between the device and initialize the same when the connection mode is cancelled when the wireless MIC 100 is out of the set range or by receiving a request command of disconnecting the pairing from the wireless MIC.

The tone adjustment input part 260 receives a command on the tone adjustment.

The volume adjustment input part 270 receives a command on the volume adjustment.

The storing part 280 temporarily stores the data from the wireless MIC in case of the connection mode.

The present invention is advantageous to provide various conveniences to a lecturer who gives lecture under an advanced lecture room environment equipped with an advanced wireless system.

As the present invention may be embodied in several forms without departing from the spirit or essential characteristics thereof, it should also be understood that the above-described examples are not limited by any of the details of the foregoing description, unless otherwise specified, but rather should be construed broadly within its spirit and scope as defined in the appended claims, and therefore all changes and modifications that fall within the meets and bounds of the claims, or equivalences of such meets and bounds are therefore intended to be embraced by the appended claims.

[Descriptions of the reference numerals of the drawings]

| | |
|---|---|
| 100: wireless MIC | 101: paring button |
| 102: volume adjustment button | 103: MUTE button |
| 110: central processing unit | 120: initialization part |
| 130: USB input terminal | 140: charge process part |
| 150: charge battery | 160: charge state judgment part |
| 170: connection state judgment part | 180: information provision part |
| 185: alarm part | 190: LED |
| 195: LCD | 200: amplifier |
| 201: wireless chips | 203: input terminal |
| 210: channel process part | 220: howling inhibition circuit |
| 230: tone adjustment circuit | 240: volume adjustment circuit |
| 250: central control part | 260: tone adjustment input part |
| 270: volume adjustment input part | 280: storing part |

1. A wireless MIC (microphone) system for automatically paring, comprising:
a wireless MIC which includes a paring button at its one side and facilitates a connection mode as it is automatically paired with an amplifier by transmitting a paring request signal when the paring button is on, and initializes a connection related information stored in a storing part when the connection mode is cancelled and converts an acoustic signal into a digital audio signal and transmits to the paired amplifier; and
an amplifier which facilitates a connection mode as the wireless MIC and the amplifier are paired by setting a transmission and receiving channel of the amplifier and the wireless MIC, and amplifies a digital audio signal from the wireless MIC and outputs in an acoustic form.

2. The system of claim 1, wherein said amplifier comprises:
a plurality of wireless receiving chips which receive a paring request signal and a digital audio signal from the plurality of the wireless MICs; and
a channel process part which allows each wireless MIC to transmits a digital audio signal by using a transmission and receiving channel based on an advanced adaptive frequency hopping method when digital audio signals are transmitted from the plurality of the wireless MICs.

3. The system of claim 2, wherein said amplifier comprises:
a howling inhibition circuit which judges whether a howling has happened by detecting a change of a digital audio signal from a wireless MIC, and eliminates a howling by adjusting a gain value of a digital audio signal when it is judged that a howling has happened.

4. The system of claim 3, wherein said amplifier comprises:
a plurality of input terminals which are formed at one side of the amplifier and receive a digital audio signal or a digital image signal from an external input device.

5. The system of claim 4, wherein said amplifier comprises:
a tone adjustment input part which receives a command on a tone adjustment;
a volume adjustment part which receives a command on a volume adjustment;
a tone adjustment circuit which modulates a digital audio signal from the wireless MIC into a corresponding frequency for thereby adjusting to a certain tone value when a request for adjusting a tone is inputted from the tone adjustment input part; and
a volume adjustment circuit which adjusts a digital audio signal from the wireless MIC to a certain volume valve when a request for adjusting a volume is received from the volume adjustment input part.

6. The system of claim 1, wherein said wireless MIC comprises:
a paring button which receives a command on a paring with an amplifier;
a central processing unit in which a paring request signal is transmitted to an amplifier when an on signal is received from the paring button, and a pin code of a wireless MIC is transmitted for a paring between the devices when a paring approval signal and a pin code of an amplifier are received from the amplifier by transmitting a paring request signal to the amplifier, and an acoustic signal is converted into a digital audio signal in the connection mode as the devices are paired and, and is transmitted to a paired amplifier; and
an initialization circuit which initializes by deleting a pin code information exchanged between the devices when a connection mode with the amplifier paired with the wireless MIC is cancelled.

7. The system of claim 6, wherein said wireless MIC comprises:
a USB input terminal which is installed at one side of the wireless MIC and receives a DC voltage of a computer; and
a charge process part which charges with a DC voltage inputted via the USB input terminal.

8. The system of claim 7, wherein wireless MIC comprises:
a LED installed at one side of the wireless MIC;
a LCD installed at one side of the wireless MIC;
a charge state judgment part which judges a charge state of a charge battery of the wireless MIC;
a connection state judgment part which judges a connection state between the wireless MIC and the amplifier; and
an information provision part which allows a result of the judgment of the charge state judgment part and the connection state judgment part to be outputted via the LED or the LCD.

9. The system of claim 8, wherein said wireless MIC comprises:
an alarm part which process to output a charge suggestion message via the LED and the LCD when a charge level is below a previously set level as a result of the judgment of the charge state judgment part and processes to transmit a short message (SMS) informing a charge suggestion to a user of the wireless MIC.
